(19) United States
(12) Patent Application Publication
(10) Pub. No.: US 2005/0132960 A1
(43) Pub. Date: Jun. 23, 2005

(54) Small volume environmental chamber and multi-chamber processing apparatus comprising same

(75) Inventor: Tatsuru Tanaka, Campbell, CA (US)

Correspondence Address: SEAGATE TECHNOLOGY LLC;c/o MCDERMOTT WILL & EMERY LLP, 600 13TH STREET, NW, WASHINGTON, DC, 20005-3096, US

(73) Assignee: SEAGATE TECHNOLOGY LLC

(21) Appl. No.: 10/739,291

(22) Filed: Dec. 19, 2003

(51) Int. Cl. C23C 16/00; B05D 5/12

(52) U.S. Cl. 118/719; 427/127

(57) ABSTRACT

Apparatus for exposing at least one substrate/workpiece to a gas atmosphere under preselected pressure and temperature conditions, comprising: (a) a chamber defining an interior space and provided with inlet and outlet means at opposite ends thereof; (b) vacuum means for evacuating the interior space and including valve means for controlling the evacuating; (c) a pair of opposingly facing gas injection means in the interior space and defining an intermediate space therebetween for accommodating the at least one substrate/workpiece during transport through the chamber, each of the gas injection means including means for controlling the temperature thereof; (d) gas supply means for supplying the pair of gas injection means with a flow of a preselected gas and including valve means for controlling the gas flow; and (e) transport means for transporting the at least one substrate/workpiece through the interior space of said chamber via the intermediate space between the opposingly facing gas injection means.

### CROSS-REFERENCE TO RELATED APPLICATIONS

This application contains subject matter related to subject matter disclosed in co-pending, commonly assigned U.S. patent applications Ser. No. ______, filed on ______ (Attorney Docket No. 50103-527); Ser. No. ______, filed on ______ (Attorney Docket No. 50103-547); Ser. No. ______, filed on ______ (Attorney Docket No. 50103-551); and Ser. No. ______, filed on ______ (Attorney Docket No. 50103-556).

### FIELD OF THE INVENTION

The present invention relates to an improved apparatus for providing a controlled environment for processing/treating substrates/workpieces as part of a multi-chamber processing/treating apparatus, e.g., an in-line multi-chamber sputtering apparatus. The invention has particular utility in automated manufacture of thin-film magnetic and magneto-optical (MO) recording media.

### BACKGROUND OF THE INVENTION

Magnetic and magneto-optical (MO) recording media are widely employed in various applications, particularly in the computer industry for data/information storage and retrieval purposes, typically in disk form. Conventional magnetic thin-film media, wherein a fine-grained polycrystalline magnetic alloy serves as the active recording layer, are generally classified as “longitudinal” or “perpendicular”, depending upon the orientation of the magnetic domains of the magnetic material relative to the surface of the media substrate.

A typical longitudinal magnetic recording medium in e.g., disk form, such as utilized in the computer-related applications, comprises a non-magnetic substrate e.g., of glass, ceramic, glass-ceramic composite, polymer, metal, or metal alloy, typically an aluminum (Al)-based alloy such as aluminum-magnesium (Al—Mg), having at least one major surface on which a layer stack comprising a plurality of thin film layers constituting the medium are sequentially deposited. Such layers may include, in sequence from the workpiece (substrate) deposition surface, a plating or adhesion layer, e.g., of amorphous nickel-phosphorus (Ni—P), a polycrystalline underlayer, typically of chromium (Cr) or a Cr-based alloy such as chromium-vanadium (Cr—V), a magnetic layer, e.g., of a cobalt (Co)-based alloy, a protective overcoat layer, typically of a carbon-based material having good mechanical (i.e., tribological) properties, and a lubricant topcoat layer, e.g., a perfluoropolyether.

A typical perpendicular magnetic recording medium in e.g., disk form, such as utilized in the computer-related applications, similarly comprises a non-magnetic substrate e.g., of glass, ceramic, glass-ceramic composite, polymer, metal, or metal alloy, typically an aluminum (Al)-based alloy such as aluminum-magnesium (Al—Mg), having at least one major surface on which a layer stack comprising a plurality of thin film layers constituting the medium are sequentially deposited. Such layers may include, in sequence from the workpiece (substrate) deposition surface, an optional plating or adhesion layer, e.g., of Ti or a Ti alloy, a magnetically soft underlayer, e.g., of a soft magnetic material such as Ni or NiFe (Permalloy), at least one interlayer of a non-magnetic material, e.g., Ru or TiCr, at least one hard magnetic recording layer, e.g., of a Co-based alloy, a protective overcoat layer, typically of a carbon-based material having good mechanical (i.e., tribological) properties, and a lubricant topcoat layer, e.g., a perfluoropolyether.

A similar situation exists with MO media, wherein a layer stack is formed on a suitable substrate, which layer stack comprises a reflective layer, typically of a metal or metal alloy, one or more rare-earth thermo-magnetic (RE-TM) alloy layers, one or more dielectric layers, and a protective overcoat layer, for functioning as reflective, transparent, writing, writing assist, read-out, and protective overcoat layers, etc.

According to conventional manufacturing methodology, a majority of the above-described layers constituting magnetic and/or MO recording media are deposited by cathode sputtering, typically by means of multi-cathode and/or multi-chamber sputtering apparatus wherein a separate cathode comprising a selected target material is provided for deposition of each component layer of the stack and the sputtering conditions are optimized for the particular component layer to be deposited. Each cathode comprising a selected target material can be positioned within a separate, independent process chamber, in a respective process chamber located within a larger chamber, or in one of a plurality of separate, interconnected process chambers each dedicated for deposition of a particular layer. According to such conventional manufacturing technology, a plurality of media substrates, typically in disk form, are serially transported by means of a multi-apertured pallet or similar type holder, in linear or circular fashion, depending upon the physical configuration of the particular apparatus utilized, from one sputtering target and/or process chamber to another for sputter deposition of a selected layer thereon.

Referring now to FIGS. 1-2, shown therein, in simplified, schematic cross-sectional top and side views, respectively, is an illustrative, but not limitative, embodiment of a conventional in-line, multi-chamber “pass-by” apparatus for treating opposing surfaces of a plurality of vertically mounted workpieces/substrates, which apparatus can, if desired, form part of a larger, in-line apparatus for continuous, automated manufacture of, e.g., magnetic and/or magneto-optical (MO) recording media, such as hard disks, and wherein a plurality of workpieces/substrates (e.g. disks) are transported in a linear path transversely past a plurality of serially arranged chambers each forming a processing/treatment station for performing a processing/treatment of each of the plurality of substrates.

More specifically, apparatus 10, as illustrated, comprises a series of linearly elongated vacuum chambers interconnected by a plurality of gate means G of conventional design, the vacuum chambers forming a plurality of treatment chambers or stations, illustratively first and second treatment chambers or stations 1 and 1′, each including at least one, preferably a pair of spaced-apart, oppositely facing, linearly elongated treatment sources 2, 2′ (e.g., selected from among a variety of physical vapor deposition (PVD) sources, such as vacuum evaporation, sputtering, ion plating, etc. sources, and/or from among a variety of plasma treatment sources, such as sputter/ion etching, hydrogen, nitrogen, oxygen, argon, etc. plasma sources) for performing simultaneous treatment of both sides of dual-sided workpieces. Apparatus 10 further includes a pair of buffer/isolation chambers such as 3, 3′ and 3′, 3″ at opposite lateral ends of respective treatment chambers or stations 1 and 1′ for insertion and withdrawal, respectively, of one or more vertically oriented workpieces/substrates, illustratively a plurality of disk-shaped substrates 4 carried by a plurality of workpiece/substrate mounting/transport means 5, 5′, e.g., perforated pallets adapted for mounting a plurality of disk-shaped substrates/workpieces, for “pass-by” transport through apparatus 10. Chambers 6, 6′ respectively connected to the distal ends of inlet and outlet buffer/isolation chambers 3, 3″ are provided for use of apparatus 10 as part of a larger, continuously operating, in-line apparatus wherein workpieces/substrates 4 receive processing/treatment antecedent and/or subsequent to processing in apparatus 10.

Apparatus 10 is, if required by the nature/mode of operation of treatment sources 2, 2′, provided with conventional vacuum means (not shown in the drawing for illustrative simplicity) for maintaining the interior spaces of each of the treatment chambers 1, 1′, etc. and buffer/isolation chambers 3, 3′, 3″, etc. at a reduced pressure below atmospheric pressure, and with means for supplying at least selected ones with an appropriate process gas (not shown in the drawing for illustrative simplicity). Apparatus 10 is further provided with a workpiece/substrate conveyor/transporter means of conventional design (not shown in the drawings for illustrative simplicity) for linearly transporting the workpiece/substrate mounting means 5, 5′ through the respective gate means G from chamber-to-chamber in its travel through apparatus 10.

When apparatus 10 is utilized in the manufacture of disk-shaped magnetic and/or MO recording media, the workpieces/substrates 4, 4′ carried by mounting means 5, 5′ are in the form of annular disks, with inner and outer diameters corresponding to those of conventional hard disk-type magnetic and/or MO media, and each of the illustrated treatment chambers 1, 1′ of apparatus 10 is provided with a pair of opposingly facing, linearly extending physical vapor deposition sources 2, typically elongated magnetron sputtering sources, for deposition of respective constituent thin films of the multi-layer magnetic or MO media on each surface of each of the plurality of disks 4, 4′ carried by the perforated pallet-type mounting means 5, 5′.

It has been determined that significant improvement in the performance characteristics and corrosion resistance of thin-film magnetic recording media requiring magnetic recording layers with well-defined, i.e., segregated grains, is obtained by exposing the magnetic recording layer to an oxygen (O₂) or oxygen-containing atmosphere prior to formation of the protective overcoat thereon. Typically, it is required that the media precursor,. i.e., the substrate with a stack of thin-film layers formed thereon and including a just-formed magnetic recording layer, be removed from the manufacturing apparatus, e.g., an in-line or circularly-configured, multi-chamber sputtering apparatus adapted for performing large-scale, automated, continuous manufacture of thin-film recording media, such as described supra, for exposure to the oxygen (O₂) or oxygen-containing atmosphere.

However, removal of the media precursor from the multi-chamber sputtering apparatus for performing the surface oxidation treatment by exposure of the media precursor to the oxygen (O₂) or oxygen-containing atmosphere (e.g., ambient atmosphere) prior to the carbon deposition step severely impacts the efficiency and manufacturing throughput of the apparatus. Specifically, additional air locks, loading and unloading means, etc., are required for removing media precursors from a continuous manufacturing apparatus in order to perform the oxidation treatment and then supplying the surface-oxidized media precursors to another manufacturing apparatus (or returning them to the previously utilized multi-chamber apparatus) for subsequent processing, e.g., protective overcoat formation. In addition, the removal of the media precursors from the manufacturing apparatus and the surface oxidation treatment via exposure to the oxygen (O₂) or oxygen-containing atmosphere disadvantageously incur an excessive increase in the overall media manufacturing interval, cost, and efficiency.

In view of the foregoing, there exists a clear need for means and methodology for manufacturing improved, high areal recording density, high performance perpendicular magnetic recording media, which means and methodology avoid the disadvantages and drawbacks associated with the above-described conventional means and methodology, and which facilitate high throughput, cost-effective, automated manufacture of such high performance perpendicular magnetic recording media.

The present invention, therefore, addresses and solves the above-described problems, drawbacks, and disadvantages relating to the poor efficiency and product throughput associated with conventional means and methodology for the manufacture of high performance perpendicular magnetic recording media, while maintaining full compatibility with all aspects of automated magnetic media manufacture.

### DISCLOSURE OF THE INVENTION

An advantage of the present invention is an improved apparatus adapted for exposing at least one substrate/workpiece to a gas atmosphere under preselected pressure and temperature conditions.

Another advantage of the present invention is an improved apparatus adapted for oxidizing the surface of a magnetic recording layer of a magnetic recording medium.

Still another advantage of the present invention is an improved multi-chamber treatment/processing apparatus.

A further advantage of the present invention is an improved multi-chamber treatment/processing apparatus including an improved treatment/processing chamber.

A still further advantage of the present invention is an improved multi-chamber treatment/processing apparatus including an improved treatment/processing chamber adapted for oxidizing the surface of a magnetic recording layer of a magnetic recording medium.

An additional advantage of the present invention is an improved method of manufacturing a magnetic recording medium.

Additional advantages and other features of the present invention will be set forth in the description which follows and in part will become apparent to those having ordinary skill in the art upon examination of the following or may be learned from the practice of the present invention. The advantages of the present invention may be realized and obtained as particularly pointed out in the appended claims.

According to an aspect of the present invention, the foregoing and other advantages are obtained in part by an apparatus adapted for exposing at least one substrate/workpiece to a gas atmosphere under preselected pressure and temperature conditions, comprising:

(a) a chamber defining an interior space, the chamber provided with inlet and outlet means at opposite ends thereof;

(b) vacuum means for evacuating the interior space of the chamber;

(c) a pair of opposingly facing gas injection means in the interior space of the chamber and defining an intermediate space therebetween for accommodating the at least one substrate/workpiece during transport through the chamber, each of the gas injection means including means for controlling the temperature thereof;

(d) gas supply means for supplying the pair of gas injection means with a flow of a preselected gas; and

(e) transport means for transporting the at least one substrate/workpiece through the interior space of the chamber via the intermediate space between the opposingly facing gas injection means.

According to embodiments of the present invention, each of the inlet means and outlet means comprises gas gate means; the transport means comprises means for mounting and transporting at least one disk-shaped substrate/workpiece through the interior space of the chamber via the inlet means and outlet means; each of the pair of gas injection means comprises a gas injection manifold comprising a plurality of passages formed in a thermally conductive block, the passages terminating in openings in the block facing the intermediate space between the pair of gas injection means; and each of the gas injection means further comprises means for heating and/or cooling the thermally conductive block.

Another aspect of the present invention is a multi-chamber treatment/processing apparatus comprising the above processing/treatment chamber.

Yet another aspect of the present invention is a multi-chamber treatment/processing apparatus, comprising:

at least first, second, and third serially arranged treatment/processing chambers, the treatment/processing chambers including inlet means and outlet means for insertion and withdrawal of substrates/workpieces from the respective interior spaces thereof; and

transport means for transporting at least one substrate/workpiece through the interior spaces of each of the chambers for treatment/processing therein; wherein:

the second treatment/processing chamber is adapted for treating/processing the at least one substrate/workpiece by exposure to a gas atmosphere under preselected pressure and temperature conditions, and comprises:

(a) vacuum means for evacuating the interior space thereof;

(b) a pair of opposingly facing gas injection means in the interior space and defining an intermediate space therebetween for accommodating the at least one substrate/workpiece during transport through the second chamber, each of the gas injection means including means for controlling the temperature thereof; and

(c) gas supply means for supplying the pair of gas injection means with a flow of a preselected gas.

According to embodiments of the present invention, each of the inlet means and said outlet means comprises gas gate means; the transport means comprises means for mounting and transporting at least one disk-shaped substrate/workpiece through the chambers via the inlet means and outlet means; each of the pair of gas injection means comprises a gas injection manifold comprising a plurality of passages formed in a thermally conductive block, the passages terminating in openings in the block facing the intermediate space between the pair of gas injection means; and each of the gas injection means further comprises means for heating and/or cooling the thermally conductive block.

Embodiments of the present invention include those wherein each of the first and third treatment/processing chambers is adapted to perform a physical vapor (PVD) deposition process selected from the group consisting of vacuum evaporation, sputtering, ion plating, ion beam deposition (IBD), and cathodic arc deposition (CAD), a chemical vapor deposition (CVD) process, or a plasma-enhanced chemical vapor deposition (PECVD) process.

Preferably, each of the first and third treatment/processing chambers is adapted to perform a sputter deposition process.

Still another aspect of the present invention is a method of manufacturing a magnetic recording medium, comprising steps of:

(a) providing a multi-chamber processing/treatment apparatus comprising at least first, second, and third serially arranged treatment/processing chambers, wherein:

the second treatment/processing chamber is adapted for treating/processing of at least one substrate by exposure to a gas atmosphere under preselected pressure and temperature conditions, and comprises:
(i) vacuum means for evacuating the interior space thereof;
(ii) a pair of opposingly facing gas injection means in the interior space and defining an intermediate space therebetween for accommodating the at least one substrate during transport through the second chamber, each of the gas injection means including means for controlling the temperature thereof; and
(iii) gas supply means for supplying the pair of gas injection means with a flow of a preselected gas;

(b) providing the first treatment/processing chamber with at least one substrate/workpiece for a magnetic recording medium;

(c) forming a magnetic recording layer on the at least one substrate in the first treatment/processing chamber;

(d) transporting the at least one substrate from the first treatment/processing chamber to the second treatment/processing chamber;

(e) treating the at least one substrate in the second treatment/processing chamber with a reactive gas under preselected pressure and temperature conditions to effect reaction of the surface of the magnetic recording layer;

(f) transporting the at least one substrate from the second treatment/processing chamber to the third treatment/processing chamber; and

(g) forming a protective overcoat layer on the reacted surface of the magnetic recording layer in the third treatment/processing chamber.

According to embodiments of the present invention, step (a) comprises providing a multi-chamber treatment/processing apparatus wherein each of the gas injection means comprises a gas injection manifold comprising a plurality of passages formed in a thermally conductive block and terminating in openings in the block facing the intermediate space between the pair of gas injection means, and each of the gas injection means further comprises means for heating and/or cooling the thermally conductive block; and step (b) comprises providing the first treatment/processing chamber with at least one disk-shaped substrate/workpiece for a magnetic recording medium.

Preferred embodiments of the present invention include those wherein (1) step (c) comprises forming a Cr-segregated, Cr-rich grain boundary, Co-based alloy perpendicular magnetic recording layer comprised of a CoCrPtX alloy, where X=at least one element selected from the group consisting of Ta, B, Mo, V, Nb, W, Zr, Re, Cu, Ag, Hf, Ir, and Y, and wherein Co-containing magnetic grains with hcp lattice structure are segregated by Cr-rich grain boundaries and (2) wherein step (c) comprises forming a granular Co-based alloy perpendicular magnetic recording layer comprised of a CoPtX alloy, where X=at least one element or material selected from the group consisting of Cr, Ta, B, Mo, V, Nb, W, Zr, Re, Ru, Cu, Ag, Hf, Ir, Y, SiO₂, SiO, Si₃N₄, Al₂O₃, AlN, TiO, TiO₂, TiOₓ, TiN, TiC, Ta₂O₃, NiO, and CoO, and wherein Co-containing magnetic grains with hcp lattice structure are segregated by grain boundaries comprising at least one of oxides, nitrides, and carbides; step (e) comprises treating the at least one substrate in the second treatment/processing chamber with an oxygen-containing gas at a preselected pressure from about 0.01 to about 100 Torr and a preselected temperature from about 5 to about 500° C.; step (g) comprises forming a carbon-containing protective overcoat layer; and steps (c) and (g) each comprise sputter deposition.

Additional advantages and aspects of the present invention will become readily apparent to those skilled in the art from the following detailed description, wherein embodiments of the present invention are shown and described, simply by way of illustration of the best mode contemplated for practicing the present invention. As will be described, the present invention is capable of other and different embodiments, and its several details are susceptible of modification in various obvious respects, all without departing from the spirit of the present invention. Accordingly, the drawings and description are to be regarded as illustrative in nature, and not as limitative.

### BRIEF DESCRIPTION OF THE DRAWINGS

The following detailed description of the embodiment of the present invention can best be understood when read in conjunction with the following drawings, in which the various features are not necessarily drawn to scale but rather are drawn as to best illustrate the pertinent features, and wherein like reference numerals are employed throughout for designating similar features, wherein:

FIG. 1 is a simplified, schematic cross-sectional top view of a portion of a multi-chamber, in-line, “pass-by” processing/treatment apparatus according to the conventional art;

FIG. 2 is a simplified, schematic cross-sectional side view of the in-line apparatus of FIG. 1;

FIG. 3 is a simplified, schematic cross-sectional top view of a portion of a multi-chamber, in-line, “pass-by” processing/treatment apparatus according to an embodiment of the present invention and comprising an in situ oxidation treatment chamber intermediate a pair of sputter deposition chambers; and

FIG. 4 is an enlarged, simplified, cross-sectional view of the in situ oxidation treatment chamber taken along line 4-4 of FIG. 3.

### DESCRIPTION OF THE INVENTION

The present invention addresses and solves product throughput and manufacturing cost-effectiveness problems associated with the manufacture of high areal recording density, high performance magnetic recording media requiring oxidation treatment of the magnetic recording layer prior to formation of a protective overcoat layer thereon. The present invention advantageously facilitates continuous, automated manufacturing of magnetic recording media, e.g., hard disks, at high product throughput rates while maintaining full compatibility with all aspects and requirements of automated manufacturing technology for such media.

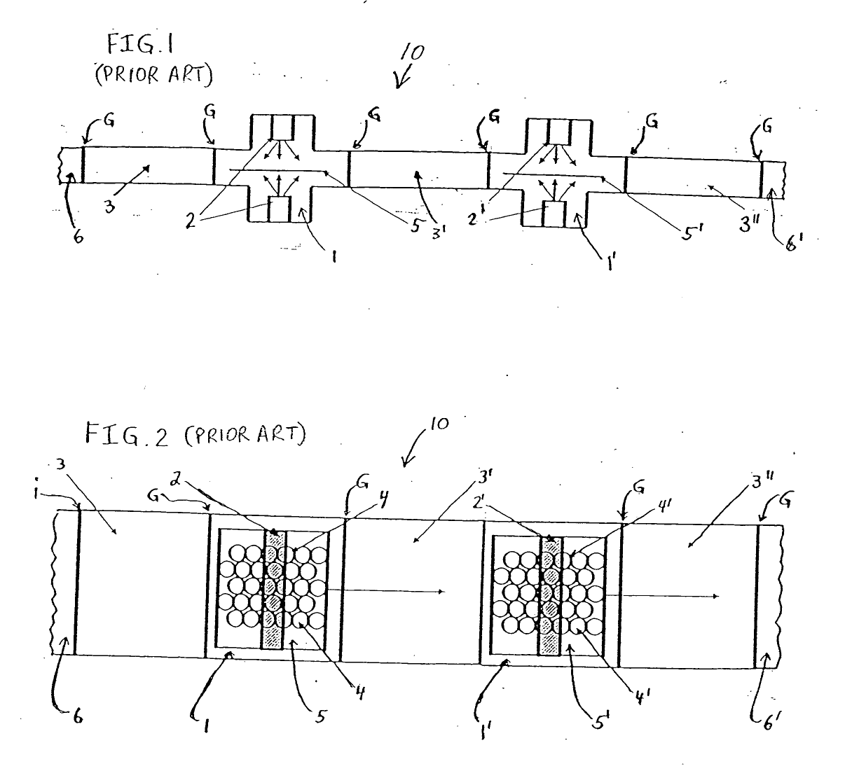

More specifically, the present invention addresses and solves problems and drawbacks associated with the approach for manufacture of high performance magnetic recording media wherein a media precursor, i.e., a media substrate with a stack of layers formed thereon, including a topmost perpendicular magnetic recording layer, is removed from the manufacturing apparatus, e.g., a sputtering apparatus, for exposure to the ambient atmosphere in order to form a surface oxide layer on the magnetic recording layer prior to deposition of a protective overcoat layer thereon, e.g., a carbon (C)-based layer, such as diamond-like carbon (DLC). As previously indicated, the sputtering apparatus typically comprises an in-line- or circularly-configured multi-chamber or similar type apparatus utilized for large-scale, automated, continuous manufacture of the magnetic recording media, e.g., apparatus such as is illustrated in FIGS. 1-2 and described above. However, removal of the media precursor from the multi-chamber sputtering apparatus for performing the surface oxidation treatment by exposure of the media precursor to the ambient atmosphere prior to the carbon deposition step severely impacts the efficiency and manufacturing throughput of the apparatus. According to the conventional methodology, additional air locks, loading and unloading means, etc., are required for removing media precursors from a continuous manufacturing apparatus in order to perform the ambient oxidation treatment and for supplying the surface-oxidized media precursors to another manufacturing apparatus (or returning them to the previously utilized multi-chamber apparatus) for subsequent processing, e.g., protective overcoat formation. In addition, the removal of the media precursors from the manufacturing apparatus and the surface oxidation treatment via exposure to the ambient atmosphere disadvantageously incur an excessive increase in the overall media manufacturing interval, cost, and efficiency.

The present invention, therefore, is based upon recognition by the inventors that the requisite post-oxidation (or other reactive) treatment of the surfaces of perpendicular magnetic recording layers of media precursors can be satisfactorily performed in rapid, efficient, and cost-effective manner, by means of an in situ post-deposition oxidation (or other reactive) process utilizing a manufacturing apparatus comprising a dedicated small-volume post-treatment chamber or station intermediate the adjacent pair of spaced-apart thin film deposition stations or chambers utilized for respectively forming the magnetic recording and protective overcoat layers. As a consequence of provision of the small-volume post-treatment station for performing the in situ post-oxidation (or other reactive) process afforded by the invention, the previous requirement for removal of the media precursors from the magnetic layer deposition station (e.g., a sputter deposition chamber) for exposure of the just-formed perpendicular magnetic layer to the ambient atmosphere for surface oxidation prior to formation of the protective overcoat layer at another deposition station is eliminated. According to the invention, therefore, the disadvantages and drawbacks associated with the conventional technology, including, inter alia: removal of the media precursor substrates from the manufacturing apparatus, the relatively long interval (e.g., from about 10 sec. to about 4 hrs.) for surface oxidation of the magnetic recording layer in the ambient (i.e., room temperature) atmosphere, and return of the surface-oxidized media precursors to the previously employed manufacturing apparatus or to another manufacturing apparatus for further processing/treatment (e.g., for protective overcoat formation) are effectively avoided, while product throughput rates are increased.

According to the invention, the small-volume chamber for in situ post-oxidation (or other reactive treatment) is configured as to simulate the above-described ex situ post-oxidation process, but at an enhanced rate and efficiency (e.g., pump-out rate) compatible with the product throughput requirements of continuous, automated manufacturing processing for magnetic recording media such as hard disks.

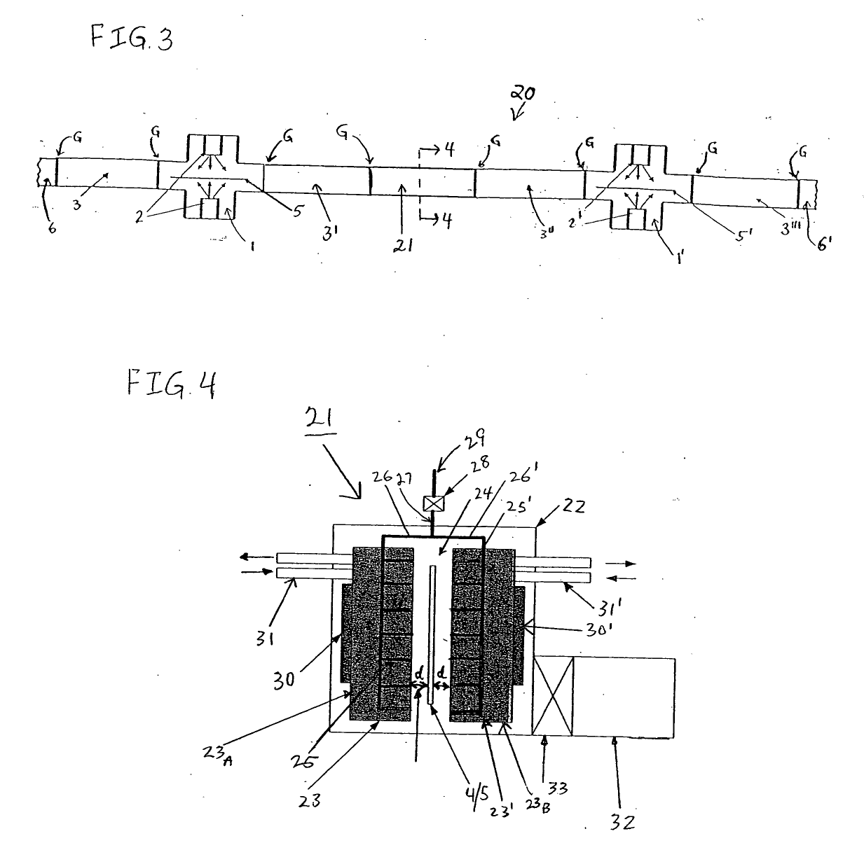

Referring now to FIG. 3-4, shown therein is a simplified, schematic cross-sectional top view of a portion of a multi-chamber, in-line, “pass-by” processing/treatment apparatus 20 according to an embodiment of the present invention and comprising an in situ post-treatment chamber 21 (e.g., a post-oxidation chamber) intermediate an adjacent pair of sputter deposition chambers 1 and 1′ such as are utilized for magnetic recording layer and protective overcoat layer formation, respectively.

More specifically, apparatus 20, as illustrated, comprises a series of linearly elongated vacuum chambers interconnected by a plurality of gate means G of conventional design, the vacuum chambers forming a plurality of treatment chambers or stations, illustratively first and second treatment chambers or stations 1 and 1′, each including at least one, preferably a pair of spaced-apart, oppositely facing, linearly elongated treatment sources 2, 2′ (e.g., selected from among a variety of physical vapor deposition (PVD) sources, such as vacuum evaporation, sputtering, ion plating, etc. sources, and/or from among a variety of plasma treatment sources, such as sputter/ion etching, hydrogen, nitrogen, oxygen, argon, etc. plasma sources) for performing simultaneous treatment of both sides of dual-sided workpieces/substrates. Apparatus 20 further includes pairs of buffer/isolation chambers such as 3, 3′; 3′, 3″; and 3″, 3′″at opposite lateral (i.e., inlet and outlet) ends of respective treatment chambers or stations for insertion and withdrawal, respectively, of one or more vertically oriented workpieces/substrates, illustratively a plurality of disk-shaped substrates 4 carried by a plurality of workpiece/substrate mounting/transport means 5, 5′, e.g., perforated pallets adapted for mounting a plurality of disk-shaped workpieces/substrates, for “pass-by” transport through apparatus 20. Chambers 6, 6′ respectively connected to the distal ends of inlet and outlet buffer/isolation chambers 3, 3′″ are provided for use of apparatus 20 as part of a larger, continuously operating, in-line apparatus wherein workpieces/substrates 4 receive processing/treatment antecedent and/or subsequent to processing in apparatus 20.

Apparatus 20 is provided with conventional vacuum means (not shown in FIG. 1 for illustrative simplicity) for maintaining the interior spaces of each of the treatment chambers 1, 1′, etc. and buffer/isolation chambers 3, 3′, 3″, 3′″, etc. at a reduced pressure below atmospheric pressure, and with means for supplying at least selected ones with an appropriate process gas (not shown in the drawing for illustrative simplicity). Apparatus 20 is further provided with a workpiece/substrate conveyor/transporter means of conventional design (not shown in the drawings for illustrative simplicity) for linearly transporting the workpiece/substrate mounting means 5, 5′ through the respective gate means G from chamber-to-chamber in its travel through apparatus 20.

When apparatus 20 is utilized in the manufacture of disk-shaped magnetic and/or MO recording media, the workpieces/substrates 4, 4′ carried by mounting means 5, 5′ are in the form of annular disks comprised of a non-magnetic material, with inner and outer diameters corresponding to those of conventional hard disc-type magnetic and/or MO media, and each of the illustrated treatment chambers 1, 1′ of apparatus 10 is provided with a pair of opposingly facing, linearly extending physical vapor deposition sources 2, typically elongated magnetron sputtering sources, for deposition of respective constituent thin films of the multi-layer magnetic or MO media on each surface of each of the plurality of disks 4, 4′ carried by the perforated pallet-type mounting means 5, 5′.

According to a preferred embodiment of the invention, apparatus 20 is further provided with a small-volume, in situ post-oxidation treatment station 21 intermediate treatment/processing chambers 1 and 1′ respectively utilized for forming magnetic recording and protective overcoat layers on each surface of each of the plurality of disks 4, 4′ , etc. carried by the perforated pallet-type mounting means 5, 5′ and operatively connected thereto via respective buffer/isolation chambers 3′ and 3″ and gas gates G.

Adverting to FIG. 4, shown therein is an enlarged, simplified, cross-sectional view of the in situ oxidation treatment station 21 taken along line 4-4 of FIG. 3. As illustrated, in situ oxidation treatment station 21 comprises a vacuum chamber 22 of generally rectangular or square cross-section, provided with a pair of spaced-apart, opposingly facing gas injection manifolds 23, 23′ defining space 24 therebetween, through which space at least one substrate/workpiece passes, typically a disk 4 mounted/carried by mounting means 5. Each gas injection manifold 23, 23′ typically is in the form of block 24_{A}, 23_{B} of a thermally conductive material, e.g., a metal such as copper, and includes a plurality of gas channels 25, 25′ extending to one side surface thereof, the end of each channel forming an opening (or nozzle) facing space 24 and the other end of each channel connected to respective manifold conduits 26, 26′. The latter are connected, via conduit 27, gas shut-off valve 28, and conduit 29 to a source of oxygen (O₂) or an oxygen-containing gas. Each gas injection manifold 23, 23′ further includes temperature regulating/controlling means, comprised of a respective heating means 30, 30′, e.g., an electrical resistance heating element, on the other side surface of respective blocks 23_{A}, 23_{B}, and a respective cooling means 31, 31′, typically comprised of a plurality of channels formed therein for circulation of a coolant fluid therethrough. Vacuum means 32, typically a pump means, is operatively connected to chamber 22 via valve means 33 for controllable evacuation of gas from chamber 22.

According to the invention, the spacing, or distance d between the nozzle-bearing surfaces of the gas distribution manifolds 23, 23′ is kept at a minimum, e.g., from about 0.01 to about 4 in., typically about 0.5 in., to ensure that the interior volume of chamber occupied by the gas is small in order to facilitate rapid establishment of a desired gas pressure during treatment and rapid pump-out upon completion of treatment. Typical flow rates of gas (e.g., O₂, an oxygen-containing gas, or another reactive gas, e.g., N₂) to chamber 22 range from about 1 to about 1,000 sccm, e.g., about 100 sccm, gas pressures within chamber 22 typically are in the range from about 0.01 to about 100 Torr, e.g., about 10 Torr, and the temperature of each of gas injection manifolds 23, 23′ is typically maintained by heating means 30, 30′ and cooling means 31, 31′ within the range from about 5 to about 500° C., e.g., about 100° C.

According to an illustrative, but not limitative, example of a typical processing sequence according to the invention, a magnetic recording layer, e.g., a Cr-segregated, Cr-rich grain boundary, Co-based alloy perpendicular magnetic recording layer comprised of a CoCrPtX alloy, where X=at least one element selected from the group consisting of Ta, B, Mo, V, Nb, W, Zr, Re, Cu, Ag, Hf, Ir, and Y, and wherein Co-containing magnetic grains with hcp lattice structure are segregated by Cr-rich grain boundaries or a granular Co-based alloy perpendicular magnetic recording layer comprised of a CoPtX alloy, where X=at least one element or material selected from the group consisting of Cr, Ta, B, Mo, V, Nb, W, Zr, Re, Ru, Cu, Ag, Hf, Ir, Y, SiO₂, SiO, Si₃N₄, Al₂O₃, AlN, TiO, TiO₂, TiOₓ, TiN, TiC, Ta₂O₃, NiO, and CoO, and wherein Co-containing magnetic grains with hcp lattice structure are segregated by grain boundaries comprising at least one of oxides, nitrides, and carbides is formed on both surfaces of annular disk-shaped, non-magnetic substrates in sputter deposition station or chamber 1 of apparatus 20 and then transported to in situ post-oxidation station 21. Upon arrival of the substrates in in situ post-oxidation station 21, vacuum valve 33 is closed and process gas(es), e.g., O₂, air, etc., supplied with an even distribution pattern to space 24 via gas channels 25, 25′ of controllably heated/cooled gas injection manifolds 23, 23′, the latter being operatively connected to a gas source via conduit 29, gas shut-off valve 28, conduit 27, respective conduits 26, 26′. Upon completion of the in situ post-oxidation treatment, gas shut-off valve 28 is closed and vacuum valve 33 opened for pump-out of the gas(es) prior to or simultaneously with transport of the post-oxidized substrates to sputter deposition station or chamber 1′ for formation of a protective overcoat layer thereon. The small volume of chamber 22 facilitates rapid pump-out for obtaining increased product throughput rates. Substrate transport rates through the in situ post-oxidation station 21 are consistent with the typical continuous transport rates of substrates/workpieces 4 through the various treatment stations of apparatus 20 in the absence of station 21, e.g., in the range from about 1 to about 100 cm/sec., preferably about 5 cm/sec.

In summary, the present invention provides means and methodology for continuous, automated fabrication of high areal density, high performane perpendicular magnetic recording media requiring formation of a surface oxide (or other type reacted) layer on the perpendicular hard magnetic recording layer, at product throughputs compatible with the requirements for cost-effective manufacture of such media, while maintaining full compatibility with all aspects of such automated manufacture. The present invention advantageously eliminates the previous requirement for removal of the media precursors from the manufacturing apparatus for oxide layer formation in the ambient atmosphere and re-installation of the oxidized media in the same or a different manufacturing apparatus for subsequent processing/treatment.

Finally, the inventive thermal oxidation treatment technique can be utilized with any type of magnetic recording media, regardless of the materials used for the substrate, adhesion layer, soft magnetic underlayer(s), interlayer(s), and recording layer(s). The post-treatment process parameters and duration are preferably optimized according to the media design and the particular continuous manufacturing apparatus utilized for the treatment to obtain the maximum benefit of the inventive methodology.

In the previous description, numerous specific details are set forth, such as specific materials, structures, processes, etc., in order to provide a better understanding of the present invention. However, the present invention can be practiced without resorting to the details specifically set forth. In other instances, well-known processing materials and techniques have not been described in detail in order not to unnecessarily obscure the present invention.

Only the preferred embodiments of the present invention and but a few examples of its versatility are shown and described in the present disclosure. It is to be understood that the present invention is capable of use in various other combinations and environments and is susceptible of changes and/or modifications within the scope of the inventive concept as expressed herein.

1. An apparatus adapted for exposing at least one substrate/workpiece to a gas atmosphere under preselected pressure and temperature conditions, comprising:
(a) a chamber defining an interior space, said chamber provided with inlet and outlet means at opposite ends thereof;
(b) vacuum means for evacuating said interior space of said chamber;
(c) a pair of opposingly facing gas injection means in said interior space of said chamber and defining an intermediate space therebetween for accommodating said at least one substrate/workpiece during transport through said chamber, each of said gas injection means including means for controlling the temperature thereof;
(d) gas supply means for supplying said pair of gas injection means with a flow of a preselected gas; and
(e) transport means for transporting said at least one substrate/workpiece through said interior space of said chamber via said intermediate space between said opposingly facing gas injection means.

2. The apparatus as in claim 1, wherein:
each of said inlet means and said outlet means comprises gas gate means.

3. The apparatus as in claim 1, wherein:
said transport means comprises means for mounting and transporting at least one disk-shaped substrate/workpiece through said interior space of said chamber via said inlet means and said outlet means.

4. The apparatus as in claim 1, wherein:
each of said pair of gas injection means comprises a gas injection manifold comprising a plurality of passages formed in a thermally conductive block, said passages terminating in openings in said block facing said intermediate space between said pair of gas injection means.

5. The apparatus as in claim 4, wherein:
each of said gas injection means further comprises means for heating and/or cooling said thermally conductive block.

6. A multi-chamber treatment/processing apparatus comprising the apparatus of claim 1.

7. A multi-chamber treatment/processing apparatus, comprising:
at least first, second, and third serially arranged treatment/processing chambers, said treatment/processing chambers including inlet means and outlet means for insertion and withdrawal of substrates/workpieces from the respective interior spaces thereof; and
transport means for transporting at least one substrate/workpiece through said interior spaces of each of said chambers for treatment/processing therein; wherein:
said second treatment/processing chamber is adapted for treating/processing said at least one substrate/workpiece by exposure to a gas atmosphere under preselected pressure and temperature conditions, and comprises:
(a) vacuum means for evacuating the interior space thereof;
(b) a pair of opposingly facing gas injection means in said interior space and defining an intermediate space therebetween for accommodating said at least one substrate/workpiece during transport through said second chamber, each of said gas injection means including means for controlling the temperature thereof; and
(c) gas supply means for supplying said pair of gas injection means with a flow of a preselected gas.

8. The apparatus as in claim 7, wherein:
each of said inlet means and said outlet means comprises gas gate means.

9. The apparatus as in claim 7, wherein:
said transport means comprises means for mounting and transporting at least one disk-shaped substrate/workpiece through said chambers via said inlet means and said outlet means.

10. The apparatus as in claim 7, wherein:
each of said pair of gas injection means comprises a gas injection manifold comprising a plurality of passages formed in a thermally conductive block, said passages terminating in openings in said block facing said intermediate space between said pair of gas injection means.

11. The apparatus as in claim 10, wherein:
each of said gas injection means further comprises means for heating and/or cooling said thermally conductive block.

12. The apparatus as in claim 7, wherein:
each of said first and third treatment/processing chambers is adapted to perform a physical vapor (PVD) deposition process selected from the group consisting of vacuum evaporation, sputtering, ion plating, ion beam deposition (IBD), and cathodic arc deposition (CAD), a chemical vapor deposition (CVD) process, or a plasma-enhanced chemical vapor deposition (PECVD) process.

13. The apparatus as in claim 12, wherein:
each of said first and third treatment/processing chambers is adapted to perform a sputter deposition process.

14. A method of manufacturing a magnetic recording medium, comprising steps of:
(a) providing a multi-chamber processing/treatment apparatus comprising at least first, second, and third serially arranged treatment/processing chambers, wherein:
said second treatment/processing chamber is adapted for treating/processing of at least one substrate by exposure to a gas atmosphere under preselected pressure and temperature conditions, and comprises:
(i) vacuum means for evacuating the interior space thereof;
(ii) a pair of opposingly facing gas injection means in said interior space and defining an intermediate space therebetween for accommodating said at least one substrate during transport through said second chamber, each of said gas injection means including means for controlling the temperature thereof; and
(iii) gas supply means for supplying said pair of gas injection means with a flow of a preselected gas;
(b) providing said first treatment/processing chamber with at least one substrate/workpiece for a magnetic recording medium;
(c) forming a magnetic recording layer on said at least one substrate in said first treatment/processing chamber;
(d) transporting said at least one substrate from said first treatment/processing chamber to said second treatment/processing chamber;
(e) treating said at least one substrate in said second treatment/processing chamber with a reactive gas under preselected pressure and temperature conditions to effect reaction of the surface of said magnetic recording layer;
(f) transporting said at least one substrate from said second treatment/processing chamber to said third treatment/processing chamber; and
(g) forming a protective overcoat layer on said reacted surface of said magnetic recording layer in said third treatment/processing chamber.

15. The method according to claim 14, wherein:
step (a) comprises providing a multi-chamber treatment/processing apparatus wherein each of said gas injection means comprises a gas injection manifold comprising a plurality of passages formed in a thermally conductive block and terminating in openings in said block facing said intermediate space between said pair of gas injection means.

16. The method according to claim 15, wherein:
step (a) comprises providing a multi-chamber treatment/processing apparatus wherein each of said gas injection means further comprises means for heating and/or cooling said thermally conductive block.

17. The method according to claim 14, wherein:
step (b) comprises providing said first treatment/processing chamber with at least one disk-shaped substrate/workpiece for a magnetic recording medium.

18. The method according to claim 14, wherein:
step (c) comprises forming a Cr-segregated, Cr-rich grain boundary, Co-based alloy perpendicular magnetic recording layer comprised of a CoCrPtX alloy, where X=at least one element selected from the group consisting of Ta, B, Mo, V, Nb, W, Zr, Re, Cu, Ag, Hf, Ir, and Y, and wherein Co-containing magnetic grains with hcp lattice structure are segregated by Cr-rich grain boundaries.

19. The method according to claim 14, wherein:
step (c) comprises forming a granular Co-based alloy perpendicular magnetic recording layer comprised of a CoPtX alloy, where X=at least one element or material selected from the group consisting of Cr, Ta, B, Mo, V, Nb, W, Zr, Re, Ru, Cu, Ag, Hf, Ir, Y, SiO₂, SiO, Si₃N₄, Al₂O₃, AIN, TiO, TiO₂, TiOₓ, TiN, TiC, Ta₂O₃, NiO, and CoO, and wherein Co-containing magnetic grains with hcp lattice structure are segregated by grain boundaries comprising at least one of oxides, nitrides, and carbides.

20. The method according to claim 14, wherein:
step (e) comprises treating said at least one substrate in said second treatment/processing chamber with an oxygen-containing gas at a preselected pressure from about 0.01 to about 100 Torr and a preselected temperature from about 5 to about 500° C. to oxidize the surface of said magnetic recording layer.

21. The method according to claim 14, wherein:
step (g) comprises forming a carbon-containing protective overcoat layer.

22. The method according to claim 14, wherein:
steps (c) and (g) each comprise sputter deposition.
